(19) United States
(12) Patent Application Publication
(10) Pub. No.: US 2002/0037477 A1
(43) Pub. Date: Mar. 28, 2002

(54) System and method of creating prism line patterns for a laser foil die

(76) Inventor: Charles J. Flynn, Greenwood, MO (US)

Correspondence Address: Pillsbury Winthrop LLp, Intellectual Property Group, 50 Fremont Street, San Francisco, CA, 94105, US

(21) Appl. No.: 09/945,349

(22) Filed: Aug. 31, 2001

Related U.S. Application Data
(60) Provisional application No. 60/230,006, filed on Sep. 5, 2000.

(51) Int. Cl. G03F 1/02; B41J 2/325; B41J 2/435; B44C 1/165; B44B 5/00

(52) U.S. Cl. 430/320; 430/1; 430/2; 430/321; 359/2; 156/234; 156/233; 347/187; 347/262; 347/264

(57) ABSTRACT

A system and method of preparing artwork for a laser foil die implement prism lines designed to interact with the diffraction grating on a layer of laser hot foil. Artwork may be selectively segmented into discrete regions; prism lines may be created by assigning a halftone value, a frequency value, and an angle for each region of the artwork. A system and method of creating a laser foil die transfer such artwork and prism lines to a blank die; when created in accordance with the present invention, a die may transfer prism lines to a layer of laser foil applied to a substrate.

The present application claims the benefit of a provisional application Ser. No. 60/230,006, filed Sep. 5, 2000, entitled “DIGITAL PRISM WITH LASER HOT FOIL PROCESS.”

### FIELD OF THE INVENTION

Aspects of the present invention relate generally to application of laser foil to a substrate, and more particularly to a system and method of preparing the artwork to be implemented on the laser foil die used in laser foil applications.

### DESCRIPTION OF THE RELATED ART

Conventional laser foil application techniques are known to adhere a layer of laser foil to a substrate using a laser foil stamp or die; the laser foil includes a diffraction grating disposed on its surface to produce various color effects depending upon the angle of incidence of reflected light and the viewing angle relative to the diffraction grating. In this context, a diffraction grating is usually understood to consist of a plurality of closely spaced parallel grooves or lines on a surface; the surface areas or facets created by the lines produce various prismatic color effects by reflecting incident light in a predictable way.

While some laser foil application methodologies are intended to create images which simulate those produced using more costly holographic foil processes, the cost reduction actually realized often varies as a function of the costs associated with preparation of artwork used to create the laser foil die. The size, intricacy, and resolution of the image to be transferred to the laser foil may represent significant complications which tend to increase costs associated with creation of a laser foil die.

### BRIEF DESCRIPTION OF THE DRAWINGS

FIG. 1 is a simplified diagram illustrating one embodiment of a laser foil application system.

FIG. 2 is a simplified diagram illustrating an original artwork image to be modified for application to a layer of laser foil using one embodiment of a laser foil application process.

FIG. 3 is a simplified diagram illustrating a modified gray scale image to be applied to a layer of laser foil using one embodiment of a laser foil application process.

FIG. 4 is a simplified flow diagram illustrating the general operational flow of one embodiment of a method of preparing artwork for use in creating a laser foil die.

FIG. 5 is a simplified flow diagram illustrating the general operational flow of one embodiment of a method of creating a laser foil die.

### DETAILED DESCRIPTION

Embodiments of the present invention overcome various shortcomings of conventional technology, providing a system and method of preparing artwork for implementation in creating a laser foil die. In accordance with one aspect of the present invention, artwork intended for use in a laser foil die may be selectively segmented into discrete regions; as set forth in detail below, prism lines may be created by assigning a halftone value, a frequency value, and an angle for each region of the artwork. A system and method of creating a laser foil die transfer such artwork and prism lines to a blank die; when created in accordance with the present invention, a die may transfer prism line patterns to a layer of laser foil applied to a substrate.

The foregoing and other aspects of various embodiments of the present invention will be apparent through examination of the following detailed description thereof in conjunction with the accompanying drawings.

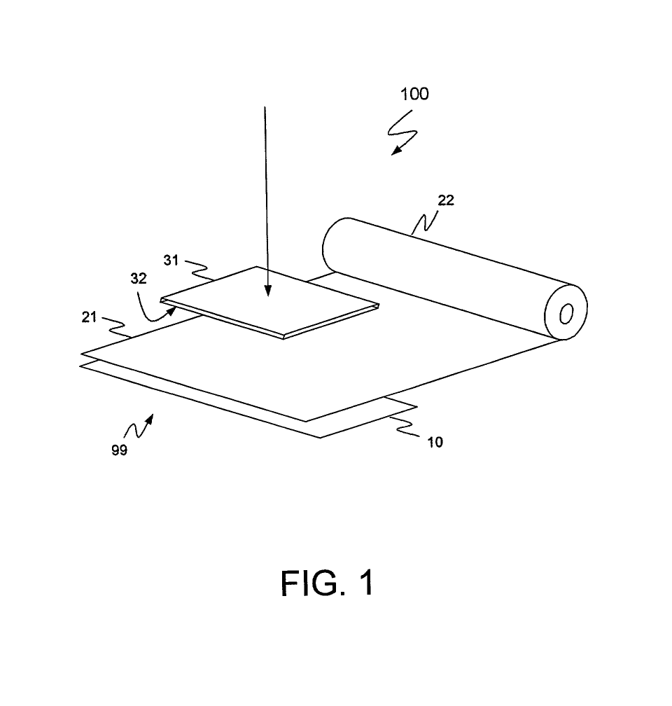

Turning now to the drawings, FIG. 1 is a simplified diagram illustrating one embodiment of a laser foil application system. In operation of system 100, laser foil 21 may be supplied from a source, such as a magazine, a ream, or a roll 22, for example, to a process area or station 99 by appropriate rollers, conveyors, gripper arms, or other mechanical transport systems. Similarly, a substrate 10, such as a greeting card, for example, may also be supplied by similar transport mechanisms from a similar source (not shown) to process station 99. At process station 99, laser foil 21 may be applied or adhered to substrate 10 by a laser foil die 31.

In that regard, sufficient pressure and heat necessary for application of laser foil 21 to substrate 10 may be provided by a stamping surface 32 of laser foil die 31. At process station 99, laser foil die 31 may stamp or otherwise exert pressure on laser foil 21 during application to substrate 10, as represented by the arrow in FIG. 1.

Laser foil 21 may be holographic hot foil or metallic foil constructed to provide prismatic color effects, reflecting light in a predetermined spectral pattern. These color effects may be produced by a diffraction grating as noted above; the diffraction grating may be comprised of closely spaced parallel grooves or lines fabricated on the surface of laser foil 21. Accordingly, laser foil 21 may generally have an inherent directional aspect, based upon the orientation of the diffraction grating. The color of light reflected by laser foil 21 may generally be a function of the angle of incidence of the reflected light as well as the viewing angle, both measured relative to the plane of laser foil 21 and to the specific orientation of the diffraction grating.

As noted briefly above, substrate 10 may be a greeting card stock for example, or other paper product such as cardboard, poster board, business card stock, and the like. Those of skill in the art will appreciate that laser foil application processes are readily adaptable to numerous additional materials which may be employed as substrate 10.

Laser foil die 31 may be constructed of ceramic or various metals, for instance, or any other material which is suitably durable to withstand the repeated application of sufficient pressure to apply or to bond laser foil 21 to substrate 10. In accordance with some embodiments, for example, laser foil die 31 may be adapted to conduct heat for the application of laser foil 21 to substrate 10; in such instances, laser foil die 31 may be constructed of a metal such as aluminum, for example, having desired or appropriate heat transfer characteristics.

Stamping surface 32 may bear an image of artwork to be transferred to laser foil 21 during the application process. As is generally known in the art, the image may be etched, carved, engraved, or otherwise modeled on stamping surface 32. Additionally, stamping surface 32 may include distinct regions of the artwork image; each region may be characterized by a pattern of prism lines created on stamping surface 32. A plurality of parallel prism lines in each image region may be operative to interact with the lines or grooves of the diffraction grating on laser foil 21, causing each image region to reflect light in a distinct way. As set forth in detail below, prism lines may be transferred to laser foil 21 by stamping surface 32 when laser foil 21 is adhered to substrate 10.

It will be appreciated that the temperatures and pressures required by system 100 may vary depending upon, for example, the nature and composition of laser foil 21 and substrate 10, the length of time stamping surface 32 of laser foil die 31 is allowed to remain in contact with laser foil 21, and other process parameters. Accordingly, the material composition, durability, and thermal properties of laser foil die 31, and particularly stamping surface 32, may be selected as a function of the specific application and system-wide process requirements.

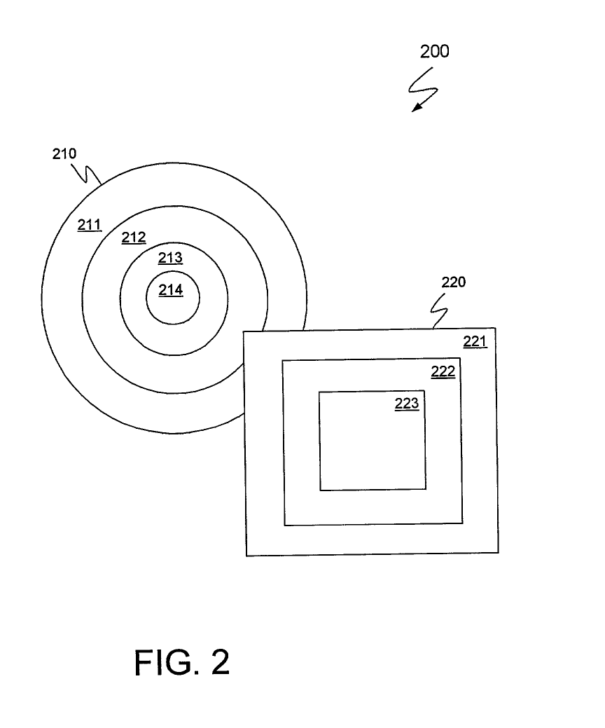

FIG. 2 is a simplified diagram illustrating an original artwork image to be modified for application to a layer of laser foil using one embodiment of a laser foil application process. As depicted in FIG. 2, an original artwork image 200 may include a generally circular component 210 and a square or rectangular component 220. Circular component 210 is illustrated as including a plurality of generally concentric, overlapping circular regions 211-214; similarly, rectangular component 220 is represented as comprising a plurality of overlapping rectangular regions 221-223. As illustrated, rectangular component 220 may overlie or obscure parts of circular component 210.

Regions 211-214 may generally represent image features or areas having identifiable or distinguishing image characteristics within circular component 210; similarly, regions 221-223 may represent features or areas within rectangular component 220 which have distinguishing image characteristics. Image features or identifiable characteristics may include such visual elements as color, texture, brightness, patterning, shading, halftoning, and the like. In FIG. 2, the interfaces between regions (such as indicated by the line between regions 211 and 212, for example, or by the line between regions 222 and 223) generally represent changes or detectable differences between the image characteristics in adjacent regions.

For example, region 211 may be characterized by a particular or distinct color in artwork image 200, whereas region 212 may be a substantially different color; additionally or alternatively, region 212 may have a different texture, brightness, or pattern than region 211. One or more isolated regions within artwork image 200 may share the same features and characteristics. For example, region 214 and region 222 may be characterized by the same color, texture, shading, and so forth; regions 214 and 222 may, nevertheless, be separated or isolated from each other by intervening regions 212, 213, and 221.

The representation of artwork image 200, image components 210 and 220, and regions 211-214 and 221-223 is provided by way of example only. It will be appreciated by those of skill in the art that numerous and varied components and regions having substantially different shapes or interrelationships may make up an image to be modified for use in a laser foil application process.

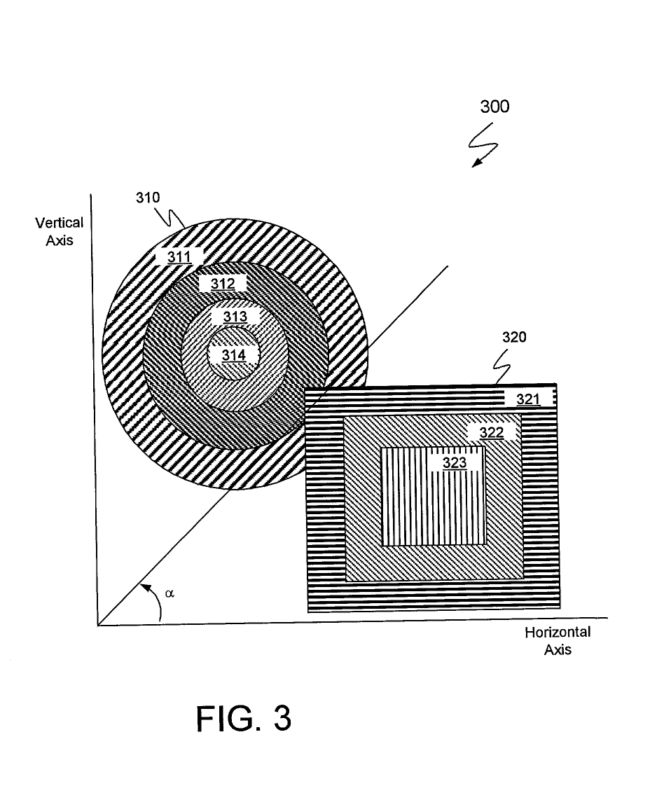

FIG. 3 is a simplified diagram illustrating a modified gray scale image to be applied to a layer of laser foil using one embodiment of a laser foil application process. As set forth in detail below, the image 300 in FIG. 3 may generally be derived from original artwork image 200 described above with reference to FIG. 2. Accordingly, image 300 may include a circular component 310, illustrated as comprising a plurality of generally concentric, overlapping circular regions 311-314, and a rectangular component 320, shown as comprising a plurality of overlapping rectangular regions 321-323. As in the FIG. 2 illustration, rectangular component 320 is depicted as overlying or partially obscuring circular component 310.

As described generally above, image components 310,320 and regions 311-314 and 321-323 may vary in number, shape, and size in accordance with the overall complexity and resolution of image 300 and original artwork image 200 from which it is derived. The following description is related particularly to preparing image 300 from original artwork such as image 200 in FIG. 2. Image 300 may be implemented in creation of a stamping surface for a laser foil die (reference numerals 32 and 31, respectively, in FIG. 1) used in laser foil application systems such as described above with reference to the system of FIG. 1.

In preparing artwork for use in creating a laser foil die, image 300 may be separated into distinct or discrete regions 311-314 and 321-323. In some embodiments employing computer hardware and software to prepare image 300, the identification of regions 311-314 and 321-323 may be enabled by software program code or firmware instructions, for example. Where image 300 is digitized, scanned, or otherwise embodied in computer-readable form, for example, image 300 may be digitally mastered or processed into a predetermined number of specified regions 311-314 and 321-323; additionally or alternatively, computer code or instructions may be configured to identify one or more regions 311-314 and 321-323 automatically, such that the number of distinct or discrete regions may vary depending up the complexity and the desired resolution of image 300.

Patterns of prism lines, generally represented by cross-hatching in FIG. 3, may be created digitally, for example, or manually by an artist. In that regard, each image region 311-314 and 321-323 may be assigned a halftone value, a frequency value, and an angle value. In accordance with this embodiment, the halftone value may represent the width of each prism line for a given region 311-314 and 321-323. The frequency value may represent the distance between, or the relative density of, the prism lines in the pattern for a given region 311-314 and 321-323; for any given halftone value, frequency may be measured, for example, in terms of lines-per-inch (LPI). The angle value for the pattern of prism lines in a given region, and in particular, any differences in the angle of the prism lines in separate image regions 311-314 and 321-323, may affect the color of light reflected from the laser foil at a given viewing angle relative to the diffraction grating, as described above.

In that regard, a prism line pattern for each distinct image region may be imprinted or transferred to laser foil by a stamping surface of a laser foil die during application of the laser foil to a substrate. The prism lines transferred to the laser foil may be operative to interact with the diffraction grating to create prismatic, multicolored effects, depending upon the halftone value and the frequency value (relative to the size and spacing of the lines on the diffraction grating) and the angle value for the prism line pattern (relative to the orientation of the lines on the diffraction grating). In some embodiments, prism lines may be substantially larger (as great as an order of magnitude or more) than the lines on the diffraction grating; alternatively, depending upon the desired prismatic effects, prism lines may be approximately the same size as the lines on the diffraction grating.

As set forth above, the halftone value and the frequency value individually assigned to each specific image region 311-314 and 321-323 may generally determine the width of the prism lines and the spacing between the prism lines, respectively. Examples of a relatively large halftone value (producing wide lines) and a relatively low frequency (few LPI) are illustrated at region 321 in FIG. 3; conversely, region 312 may be characterized as having a low halftone value (producing narrow lines) and a high frequency (many LPI) relative to region 321. In some laser foil applications, frequencies may be as high as 120 LPI or more, for example.

As indicated in FIG. 3, the prism lines in each identifiable region 311-314 and 321-323 may generally be oriented at a desired or specified angle, α, relative to a reference axis or a system of coordinate axes. As represented in FIG. 3, angle a is measured relative to an horizontal reference axis defined on image 300, though it will be appreciated that any other suitable angle measurement, coordinate system, or reference axis may be used.

As noted above and illustrated in FIG. 3, image 300 may contain many different regions 311-314 and 321-323; depending upon the composition of image 300, and the original artwork image 200 from which it is derived, each identified region 311-314 and 321-323 may be assigned unique values for each individual prism parameter (halftone, frequency, and angle), or a distinct combination of the individual prism parameters. On the other hand, it is also possible that two geographically separate or isolated regions of a given image may be assigned the same values for some, or all three, prism parameters. For example, regions 314 and 322 are illustrated in FIG. 3 as having the same line width, line frequency, and angle. This similarity in prism line patterns, based upon assigned prism parameter values, may generally represent, for example, similar image characteristics displayed in regions 214 and 222 of the original artwork 200 from which image 300 is derived.

Following appropriate preparation of image 300 as set forth above, a film or template bearing a representation of image 300 and distinct regions 311-314 and 321-323 (and their associated prism lines) may be produced for creation of a laser foil die. As is generally known in the art, a film or template may be obtained from various film printers, such as a typesetting device, an imagesetter, or a Linotronic printer. The foregoing printing devices may process a digital representation of image 300 to create a template for use in exposing a blank laser foil die. In that regard, a blank laser foil die may be coated with a light sensitive resist, for example, and exposed with the film interposed between the die and the light source such that only selected areas of the blank die and resist are exposed. Following exposure, the die may be etched such that a representation of the image on the film is transferred to the surface of the die. Residual resist may then be removed.

As noted above, laser foil processes require implementation of a laser foil die having a stamping surface bearing an etching of the artwork to be applied. A layer of laser foil may be applied to paper, card stock, or other appropriate substrate using the laser foil die. Embodiments of the present invention may employ a digitally created prism line pattern transferred to a specially prepared laser foil die stamping surface such as that described above with reference to FIGS. 1 and 3. The prism lines may be imprinted onto the laser foil during application, creating desired light reflection and color dispersion characteristics.

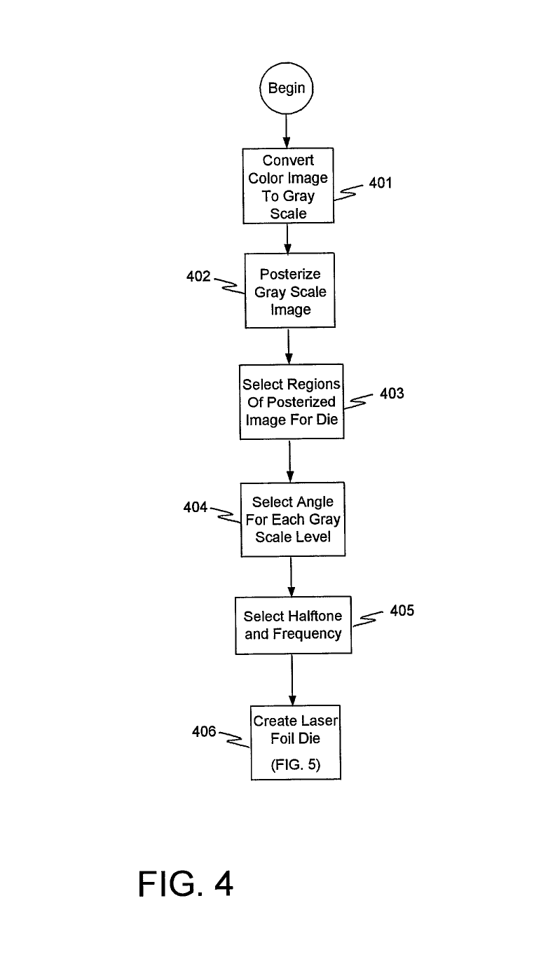

FIG. 4 is a simplified flow diagram illustrating the general operational flow of one embodiment of a method of preparing artwork for use in creating a laser foil die. While aspects of the FIG. 4 embodiment are described in detail as being carried out by a computer or a computerized system, it will be appreciated that many of the processes involved do not require use of a computer, and may rather be implemented manually by an artist, for example.

Initially, as indicated at block 401, an original color image, such as artwork image 200 described above with reference to FIG. 2, for example, may be converted to a gray scale image. Gray scale conversion may be facilitated by a computer; in a computerized embodiment, original color artwork may be created in digital form using a computer graphic program application, for instance, or scanned from another medium into digital form using any of various scanning or digitizing devices known in the art. Numerous gray scale conversion techniques may be employed by such computer-executable graphic applications. Alternatively, color artwork may be photographed using black and white film, for example, or copied using a black and white photocopier before digitizing. Additionally or alternatively, various methods of manually (i.e. without the assistance of a computerized system or device) converting a color image to a gray scale image are within the scope and contemplation of the present disclosure.

As represented at block 402, a gray scale image may be “posterized,” or limited to a selected or a predetermined number of gray scale levels. By way of example, an intricate original artwork image converted to gray scale may include numerous gray scale levels that differ only slightly; a typical computerized gray scale range may include as many as 256 discrete levels of gray, gradually varying from light to dark. A method of preparing artwork for use in creating a laser foil die may selectively limit the number of gray scale levels embodied in the modified image through posterization, which may be computer-assisted or conducted manually.

Depending upon the complexity and the resolution of the original artwork image, the range of differing gray levels present in the gray scale image, and the desired intricacy of the final modified image to be transferred to the laser foil, the posterized gray scale image may be limited to 10 or fewer gray scale levels, for example. In some embodiments, the posterized gray scale image may be limited to between 4 and 7 distinct levels of gray. It is noted that in some computer-assisted embodiments, 100% white and 100% black may always represent two gray scale levels resulting, by default, from posterization.

By way of example, a computerized posterization process may involve dividing the entire gray scale spectrum into a predetermined number of gray scale levels desired in the posterized image. Where five gray scale levels are desired, for instance, 100% white, 100% black, and three additional, equally spaced reference points may be selected from points along the gray scale spectrum (in this case, 25% white, 50% white, and 75% white). Each specific level of gray in the gray scale image may then be assigned to one of the five posterized levels in accordance with its relationship or proximity to the gray scale levels of the reference points. Additionally or alternatively, some or all of the posterization process may be executed manually, for example, by an artist.

Specified or desired regions of the posterized image may be selected (as indicated at block 403) for implementation in creating the laser foil die. Selected regions will be transferred to the stamping surface of the laser foil die as generally described above, such that the laser foil applied to a substrate will depict selected regions. Selection of regions for the laser foil die may be made automatically, for example, by computer instructions and program code operating in accordance with predetermined parameters. Additionally or alternatively, regions of the posterized image to be used in creating the laser foil die may be selected exclusively by, or under the supervision or direction of, a computer operator, a graphic artist, or other system administrator responsible for making decisions regarding aesthetics.

By way of example, regions selected for inclusion in a laser foil die are depicted in FIG. 3 and designated by reference numerals 311-314 and 321-323. As described in detail above, each selected region may be assigned an angle, α, which may determine the direction of the prism lines (relative to a reference axis, such as the horizontal axis in FIG. 3) for that region. In some embodiments, as indicated at block 404, a specific angle may be selected for each distinct gray scale level (as determined by the posterization process at block 403, for example) employed in the image.

In the example above utilizing only five gray scale levels, each of the five gray scale levels may be assigned a unique angle at block 404. In accordance with this embodiment, and referring back to the regions illustrated in FIG. 3, the direction of the respective prism line patterns indicates that regions 312, 314, and 322 may share one gray scale level, while regions 311 and 313 may share a different gray scale level; the prism lines for both regions 311 and 313 are oriented at an angle a relative to the horizontal axis, and the prism lines for all of the regions 312, 314, and 322 are oriented at an angle perpendicular to a. It will be appreciated by comparison of regions 311 and 313 that the gray scale level and the prism line angles may be entirely independent of halftone value and frequency value. In some embodiments, however, assignment of halftone values and frequency values (block 405) may be a function of gray scale level.

As indicated at block 405, each region or gray scale level may be assigned a halftone value and a frequency value. As noted above, the halftone value may generally represent the width or size of the prism lines for a particular region, and the frequency (measured in LPI, for example) may generally represent the spacing, or relative density, of the prism lines.

Following preparation of the image in accordance with the foregoing description, a laser foil die bearing the prepared image on a stamping surface may be created (block 406).

It will be appreciated that various alternatives exist with respect to the FIG. 4 embodiment, and that the presented order of the individual blocks is not intended to imply a specific sequence of operations to the exclusion of other possibilities. For example, the sequence of events depicted in blocks 403 and 404, as well as those depicted in blocks 404 and 405, may be reversed as appropriate or desired; the particular application and overall system requirements may dictate the most efficient or desirable sequence of the operations set forth in FIG. 4.

As noted above, laser foil is generally holographic or metallic foil having a diffraction grating on its surface; the typical diffraction grating is capable of producing different prismatic color effects depending upon the viewing angle. In accordance with the FIG. 4 embodiment, a digital image may be prepared for use in creating a laser foil die having a stamping surface with distinguishable prism line patterns for each image region; i.e. each region is assigned a halftone value, a frequency value, and an angle determining the orientation of the prism lines relative to a reference axis. Because the prism lines of the image regions may be oriented in different directions, the appearance of each image region may change independently as the viewing angle is changed.

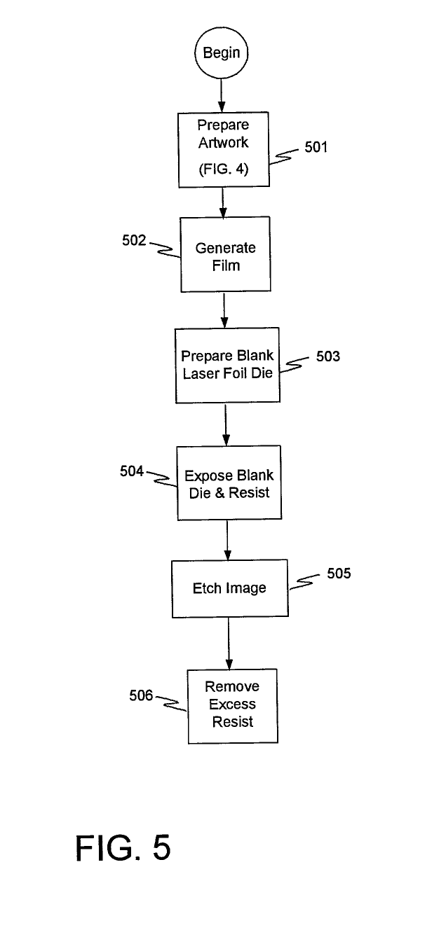

FIG. 5 is a simplified flow diagram illustrating the general operational flow of one embodiment of a method of creating a laser foil die. In the FIG. 5 embodiment, the laser foil die may be manufactured from a piece of aluminum, for example, or other metal having appropriate strength, thermal properties, and heat transfer characteristics. A desired image may be photo-etched or acid-etched, for example, onto the stamping surface of a blank die as generally described below.

The artwork or image to be transferred to a blank die may be prepared (at block 501) as set forth in detail above with reference to FIGS. 2-4.

A film or template bearing a representation of the prepared image, its distinct regions, and the associated prism line patterns may be generated as indicated at block 502. Generation of the film may be facilitated by a computer, for example; in cases where artwork has been prepared manually by an artist, for instance, a scanner or digitizing device may be used to simplify generation and preparation of the film at block 502. As described above with reference to FIG. 3, a film or template may be obtained from various printing equipment, such as, for example, a typesetting device, an imagesetter, or a Linotronic printer.

A blank laser foil die may be prepared as depicted at block 503. Preparation of the blank die may include application of a coating of light sensitive resist, for example, onto the blank stamping surface. The resist or other coating material may be polymerized or otherwise structurally altered when exposed to selected wavelengths of electromagnetic radiation. Various resists and preparation processes are generally known in the art.

The prepared blank die may then be exposed (block 504) to a light source or other source of energy at a wavelength designed to work in conjunction with the particular type of resist applied to the blank stamping surface. During the exposure indicated at block 504, the die and the resist coating may be exposed while the film generated at block 502 is interposed between the die and the energy source. Accordingly, only selected portions of the resist are exposed, and a representation of the image on the film may be transferred to the stamping surface of the die.

Following exposure, appropriate portions of the resist and the die may be etched (block 505) such that the image represented on the film is transferred to the stamping surface of the die. Various etching methods are generally known in the art, and may be selected as a function of the resist used, the composition of the stamping surface of die to be etched, and other factors. Any residual resist remaining after the etching process may then be removed, as indicated at block 506.

As noted above with reference to FIG. 4, various alternatives exist with respect to the FIG. 5 embodiment, i.e. the presented order of the individual blocks is not intended to imply a specific sequence of operations. The sequence of events depicted in blocks 502 and 503, for example, may be reversed or conducted simultaneously as appropriate or desired, depending upon the particular application. Alternatively, preparation of the blank die (block 503) may precede preparation of the artwork (block 501) and generation of the film (block 502).

A laser foil die created in accordance with the FIG. 5 embodiment may include prism lines created through digital assignment of a halftone value, a frequency (in LPI, for example), and an angle for each region of the modified image. The stamping surface of the die may then be used to adhere laser foil to paper, card stock, or other substrate as described above. In operation, such a laser foil die may transfer a pattern of prism lines into the surface of the laser foil during the application process; as set forth in detail above, these prism lines may be operative to interact with the diffraction grating on the laser foil to create desired prismatic color effects. Distinct prism line patterns in the image regions may be characterized by halftone, frequency, and angle parameters, causing each image region to display or to reflect distinct color effects.

Several features and aspects of the present invention have been illustrated and described in detail with reference to particular embodiments by way of example only, and not by way of limitation. Those of skill in the art will appreciate that alternative implementations and various modifications to the disclosed embodiments are within the scope and contemplation of the invention. Therefore, it is intended that the invention be considered as limited only by the scope of the appended claims.

What is claimed is:

1. A method of preparing artwork for implementation in creating a laser foil die;
said method comprising:
providing an image to be transferred to a laser foil die;
selectively identifying a plurality of regions in said image; and
creating a pattern of prism lines for each of said plurality of regions.

2. The method of claim 1 wherein said providing an image comprises converting a color image to gray scale.

3. The method of claim 1 wherein said providing an image comprises selectively limiting said image to a selected number of gray scale levels.

4. The method of claim 3 wherein said selectively limiting is executed in accordance with a predetermined number of gray scale levels.

5. The method of claim 3 wherein said selectively limiting comprises executing a posterization process.

6. The method of claim 3 wherein said selectively identifying is executed in accordance with said selectively limiting.

7. The method of claim 1 wherein said selectively identifying comprises identifying a predetermined number of regions.

8. The method of claim 1 wherein said creating a pattern comprises selecting an angular orientation for said prism lines.

9. The method of claim 1 wherein said creating a pattern comprises selecting a halftone value and a frequency value for said prism lines.

10. The method of claim 1 further comprising generating a film in accordance with said selectively identifying and said creating.

11. The method of claim 10 wherein said selectively identifying, said creating, and said generating are executed with the assistance of a computerized system.

12. A method of creating a laser foil die; said method comprising:
preparing an image having a plurality of regions, each of said plurality of regions comprising a pattern of prism lines;
generating a film from said image, wherein said pattern of prism lines for each of said plurality of regions is transferred to said film; and
transferring said image from said film to a blank stamping surface of a laser foil die, wherein said pattern of prism lines for each of said plurality of regions is transferred to said stamping surface.

13. The method of claim 12 wherein said preparing an image comprises selectively limiting said image to a selected number of gray scale levels.

14. The method of claim 13 wherein said selectively limiting comprises executing a posterization process to limit said image to a predetermined number of gray scale levels.

15. The method of claim 12 wherein said preparing an image comprises selectively assigning an angular orientation, a halftone value, and a frequency value for said pattern of prism lines for each of said plurality of regions.

16. The method of claim 12 wherein said generating a film comprises processing said image in a digital printing device.

17. The method of claim 12 wherein said transferring comprises executing an etching process.

18. A computer readable medium encoded with data and computer executable instructions for creating artwork for use in creating a laser foil die; the data and instructions causing an apparatus executing the instructions to:
produce an image to be transferred to a laser foil die;
selectively identify a plurality of regions in said image; and
create prism lines for each of said plurality of regions.

19. The computer readable medium of claim 18 further encoded with data and instructions, further causing an apparatus to convert an original color image to gray scale.

20. The computer readable medium of claim 18 further encoded with data and instructions, further causing an apparatus to limit said image to a selected number of gray scale levels.

21. The computer readable medium of claim 18 further encoded with data and instructions, further causing an apparatus to execute a posterization process.

22. The computer readable medium of claim 20 further encoded with data and instructions, further causing an apparatus to identify said plurality of regions in accordance said selected number of gray scale levels.

23. The computer readable medium of claim 18 further encoded with data and instructions, further causing an apparatus to select an angular orientation, a halftone value, and a frequency value for said prism lines.

24. The computer readable medium of claim 18 further encoded with data and instructions, further causing an apparatus to generate a film comprising a representation of said plurality of regions and said prism lines.

25. A laser foil application system comprising:
a laser foil source operative to provide laser foil to a process station;
a substrate source operative to provide a substrate to said process station; and
a laser foil die operative to adhere said laser foil to said substrate at said process station; said laser foil die comprising means for selectively transferring prism lines to said laser foil.

26. The system of claim 25 wherein said means for selectively transferring prism lines comprises:
a stamping surface, associated with said laser foil die, bearing a representation of an image to be transferred to said laser foil; said image comprising a plurality of regions, each of said plurality of regions characterized by a distinct pattern of said prism lines represented on said stamping surface.

27. The system of claim 25 further comprising:
laser foil transport means for transporting said laser foil from said laser foil source to said process station; and
substrate transport means for transporting said substrate from said substrate source to said process station.

28. The system of claim 25 wherein said laser foil die transfers heat to said laser foil.

29. A laser foil die comprising:
a stamping surface bearing an image to be transferred to a layer of laser foil during application thereof to a substrate; said image comprising a plurality of regions, and said stamping surface comprising a pattern of prism lines for each of said plurality of regions.

30. The laser foil die of claim 29 wherein said prism lines are operative to interact with a diffraction grating on said laser foil, and wherein said stamping surface is operative to transfer said prism lines to said laser foil during application thereof to said substrate.

31. The laser foil die of claim 29 wherein said pattern of prism lines for each of said plurality of regions is characterized by a halftone value, a frequency value, and an angle value.

32. The laser foil die of claim 29 wherein said stamping surface further comprises a distinct pattern of prism lines for each of said plurality of regions.
